(19) United States
(12) Patent Application Publication
(10) Pub. No.: US 2019/0204255 A1
(43) Pub. Date: Jul. 4, 2019

(54) METHOD AND DEVICE FOR DETECTION OF METAL AND NON-METAL PARTICLE CONCENTRATION OF ELECTRICAL DISCHARGE MACHINING LIQUID

(71) Applicant: National Central University, Taoyuan City (TW)

(72) Inventors: Shih-Jui CHEN, Taipei City (TW); Dong-Lin CHUANG, New Taipei City (TW); Biing-Hwa YAN, Taoyuan City (TW); Yean-Ren HWANG, Taipei City (TW); Yi-Li CHEN, Taipei City (TW)

(21) Appl. No.: 15/895,413

(22) Filed: Feb. 13, 2018

(30) Foreign Application Priority Data
Jan. 2, 2018 (TW) 107100003

(51) Int. Cl. G01N 27/22; G01R 27/26; B23H 7/36

(52) U.S. Cl. CPC G01N 27/221; B23H 2600/00; B23H 7/36; G01R 27/2605

(57) ABSTRACT

A method and a device for detection of metal and non-metal particle concentration of an electrical discharge machining liquid are disclosed. The method comprises steps of: (A) filling a tank with the electrical discharge machining liquid, wherein the tank comprises a tank wall, a first conductor, and a second conductor; (B) measuring a voltage between the first conductor and the second conductor by an electronic device, wherein the electronic device electrically connects to the first conductor and the second conductor, and the electronic device comprises a capacitance detection circuit; and (C) calculating a particle concentration or an equivalent dielectric constant of the electrical discharge machining liquid on the basis of the measured voltage.

### CROSS REFERENCE TO RELATED APPLICATION

This application claims the benefits of the Taiwan Patent Application Serial Number 107100003, filed on Jan. 2, 2018, the subject matter of which is incorporated herein by reference.

### BACKGROUND OF THE INVENTION

### 1. Field of the Invention

The present invention relates to a method and device for detecting metal and non-metal particle concentration of electrical discharge machining liquid. More specifically, the present invention relates to a method and device for calculating particle concentration and equivalent dielectric constant of electrical discharge machining liquid by detecting a voltage.

### 2. Description of Related Art

Electrical discharge machining (EDM) is a non-traditional machining method, which is to immerse a conductive electrode and workpiece in an EDM liquid and apply a high voltage to the conductive electrode and workpiece. The high temperature, which is caused by the discharge process of the electrode and workpiece, can be used to locally melt or vaporize the surface of the workpiece to achieve the goal of machining. Hence, it can be applied to manufacturing precise, complex, and tiny elements such as aerospace engines, medical treatment, molds, optoelectronic industries, and the like.

The role of the EDM liquid is to remove the machining powder or particles, provide insulation recovery, cool the heated parts, etc. When there are excessive powders and particles present in the EDM liquid, the machining quality will be affected. However, renewing the EDM liquid too early will increase unnecessary cost. Currently, the renewal of EDM liquid depends on human judgement easily resulting in errors. Thereby, it affects machining quality and increases cost.

Therefore, it is desired to develop a method for detection of EDM liquid to determine the contamination level of EDM liquid under various machining condition, and provide a reference standard for the renewal of EDM liquid to decrease the errors caused by human judgements.

### SUMMARY OF THE INVENTION

The object of the present invention is to apply a method and device for detection of EDM liquid, which can immediately detect the contamination level of the EDM liquid so as to precisely determine the timing for renewal of the EDM liquid. Thus, it will decrease errors caused by human judgments.

To achieve the aforementioned object, the present invention provides a method for detection of electrical discharge machining liquid, comprising steps of: (A) filling a tank with an electrical discharge machining liquid, wherein the tank comprises a tank wall, a first conductor, and a second conductor; (B) measuring a voltage between the first conductor and the second conductor by an electronic device, wherein the electronic device electrically connects to the first conductor and the second conductor, and the electronic device comprises a capacitance detection circuit; and (C) calculating a particle concentration or an equivalent dielectric constant of the electrical discharge machining liquid on the basis of the measured voltage.

According to one preferred embodiment of the present invention, the step (C) may calculate a capacitance on the basis of the measured voltage, and calculate the particle concentration or the equivalent dielectric constant of the electrical discharge machining liquid on the basis of the capacitance. Furthermore, it may calculate the particle concentration of the electrical discharge machining liquid on the basis of comparing the capacitance with a database of capacitance versus particle concentration. It may be used to detect a contamination level of the electrical discharge machining liquid so as to precisely determine the timing for renewal of the electrical discharge machining liquid. Thus, it will decrease errors caused by human judgments.

According to another preferred embodiment of the present invention, the step (C) may calculate a capacitance on the basis of the measured voltage, and calculate the particle concentration or the equivalent dielectric constant of the electrical discharge machining liquid on the basis of the capacitance. Furthermore, it may identify a particle type of the electrical discharge machining liquid on the basis of comparing the equivalent dielectric constant to a database of dielectric constant versus particle type. Hence, it can be used to confirm the type of machining debris contained in the electrical discharge machining liquid to prevent contamination during machining.

The present invention provides a detection device, comprising: a tank comprising: a tank wall, having a first through hole and a second through hole; a first conductor disposed in the tank; and a second conductor disposed in the tank and disposed opposite to the first conductor; wherein the first through hole and the second through hole are connected by the tank; and an electronic device comprising a capacitance detection circuit; wherein the electronic device is electrically connected to the first conductor and the second conductor.

According to one preferred embodiment of the present invention, the first conductor and the second conductor may be thin plate conductors, and the first conductor and the second conductor may be disposed in parallel.

According to another preferred embodiment of the present invention, the first conductor may be a cylindrical conductor, the second conductor may be a cylindrical conductor shell, the cylindrical conductor and the cylindrical conductor shell may have the same central axis, and the first conductor may be disposed inside the second conductor.

The detection device in one preferred embodiment of the present invention may further comprise an electromagnetic driving device disposed at the first through hole. The electrical discharge machining liquid may be drained into the tank of the detection device by the electromagnetic driving device so as to detect a contamination level of the electrical discharge machining liquid in real time.

The electronic device in one preferred embodiment of the present invention may further comprise a microprocessor chip to process a desired function, for example but not limited to, for calculating a capacitance.

The present invention applies a simplified detection device and simple method for detection of electrical discharge machining liquid to measure the contamination level of the electrical discharge machining liquid in real time, and thereby precisely determine the timing for renewal of the electrical discharge machining liquid. Thus, it may save cost and decrease errors by human judgments.

In the present invention, preferably, the electrical discharge machining liquid comprises a non-metal particle, a metal particle, or a combination thereof. More preferably, the non-metal particle is alumina, silicon, carbon, or a combination thereof; and the metal particle is iron, gold, or a combination thereof.

Other objects, advantages, and novel features of the invention will become more apparent from the following detailed description when taken in conjunction with the accompanying drawings.

### BRIEF DESCRIPTION OF THE DRAWINGS

FIG. 1 shows a schematic diagram of a detection device of the present invention.

FIG. 2 shows a schematic diagram of another detection device of the present invention.

FIG. 3 shows a block diagram of a signal input electronic device of the present invention.

FIG. 4 shows a schematic diagram of an electronic device of the present invention.

FIG. 5 shows a schematic diagram of a method for detection of an EDM liquid of the present invention.

FIG. 6 shows a correlation between a capacitance of an EDM liquid having carbon particles and a particle concentration.

FIG. 7 shows a correlation between a capacitance of an EDM liquid having iron particles and a particle concentration.

### DETAILED DESCRIPTION OF THE PREFERRED EMBODIMENT

Although the present invention is explained in relation to its preferred embodiment, it is to be understood that many other possible modifications and variations can be made without departing from the spirit and scope of the invention as hereinafter claimed.

Furthermore, ordinal numbers such as “first”, “second” and the like used in the specification and claim for modifying elements of the claim do not mean and represent the claimed elements have any antecedent ordinal number, nor do they represent the order or sequence of production between claimed elements. The ordinal numbers are only used to clearly distinguish certain claimed elements having the same name.

### Embodiment 1

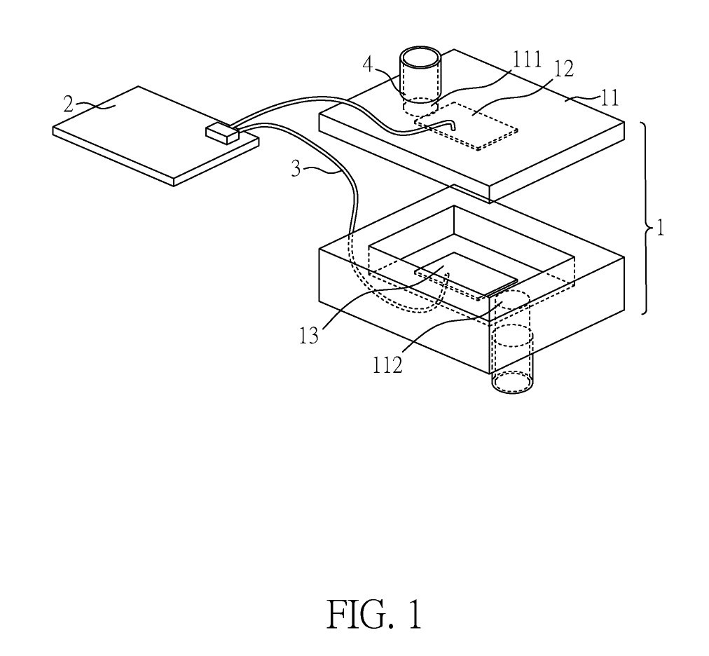

FIG. 1 shows a schematic diagram of a detection device of the present invention. The detection device of the present embodiment comprises: a tank 1, comprising: a tank wall 11, having a first through hole 111 and a second through hole 112; a first conductor 12 disposed in the tank 1; and a second conductor 13 disposed in the tank 1 and disposed opposite to the first conductor 12; wherein the first through hole 111 and the second through hole 112 are connected by the tank 1; and an electronic device 2, comprising a capacitance detection circuit 21; wherein the electronic device 2 is electrically connected to the first conductor 12 and the second conductor 13. The first conductor 12 and the second conductor 13 of the present embodiment are thin plate conductors, and the first conductor 12 and the second conductor 13 are disposed in parallel.

Herein, the positions and sizes of the first through hole 111 and the second through hole 112 are not limited, as long as they allow the EDM liquid flows into the tank 1 through the first through hole 111, filled between the first conductor 12 and the second conductor 13, and flow out through the second through hole 112. The EDM liquid may, by way of example and not limitation, be kerosene.

Herein, the material of the tank 1, which is an electric insulating material, may, by way of example and not limitation, be plastic. In addition, the material of the first conductor 12 and the second conductor 13, which is conductive material, may, by way of example and not limitation, be aluminum, silver, copper, gold and iron. Furthermore, the first conductor 12 and the second conductor 13 may be electrically connected to the electronic device 2 through metal wires 3. The material of the metal wire 3 may, by way of example and not limitation, be aluminum wire or copper wire.

FIG. 3 shows a block diagram of a signal input electronic device of the present invention. The electronic device 2 comprises a capacitance detection circuit 21. When the signal is input into the electronic device 2, the capacitance detection circuit 21 converts the measured value, and then the signal will be output. The capacitance detection circuit 21 may comprise a rectifier circuit to rectify the signal. The electronic device 2 according to another embodiment of the present invention may further comprise a signal regulating circuit 22. When a signal is input into the electronic device 2, the capacitance detection circuit 21 converts the measured value; then the signal is amplified, corrected, or filtered by the signal regulating circuit 22, and finally the signal will be output.

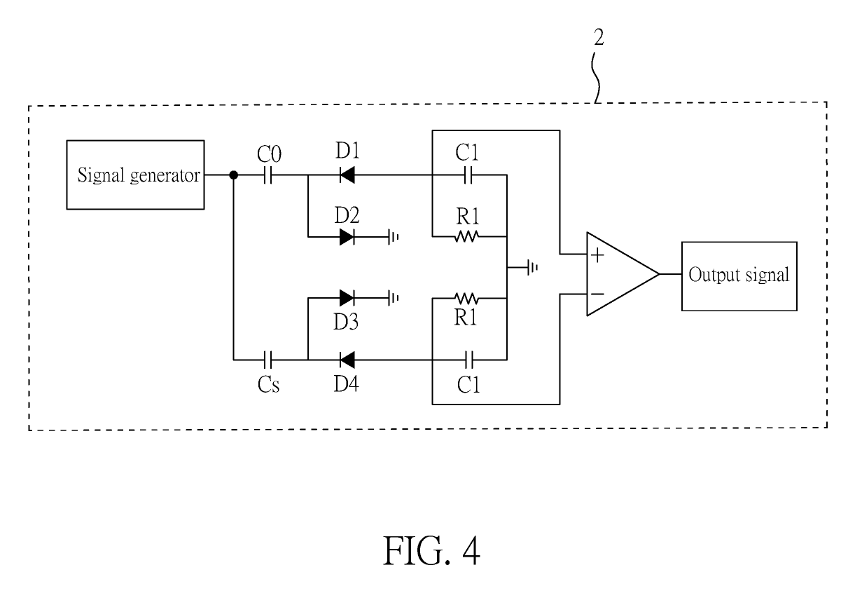

The capacitance detection circuit 21 may, by way of example and not limitation, be an AC bridge circuit, a charge/discharge circuit, or an oscillator circuit. The rectifier circuit may, by way of example and not limitation, be a half-wave rectifier circuit, a double half-wave rectifier circuit, or a bridge rectifier circuit. The signal regulating circuit 22 may, by way of example and not limitation, be a correcting circuit, an amplification circuit, or a filtering circuit. FIG. 4 shows a schematic diagram of an electronic device 2 of the present invention; wherein the capacitance detection circuit 21 is an AC bridge circuit, the rectifier circuit is a half-wave rectifier circuit, and the signal regulating circuit 22 is an amplification circuit.

In addition, the detection device may further comprise an electromagnetic driving device 4 disposed at the first through hole 111. The EDM liquid may be drained into the tank 1 of the detection device by the electromagnetic driving device 4 so as to instantly detect the contamination level of the EDM liquid.

Furthermore, the electronic device 2 may further comprise a microprocessor chip, for example but not limited to, a single chip.

### Embodiment 2

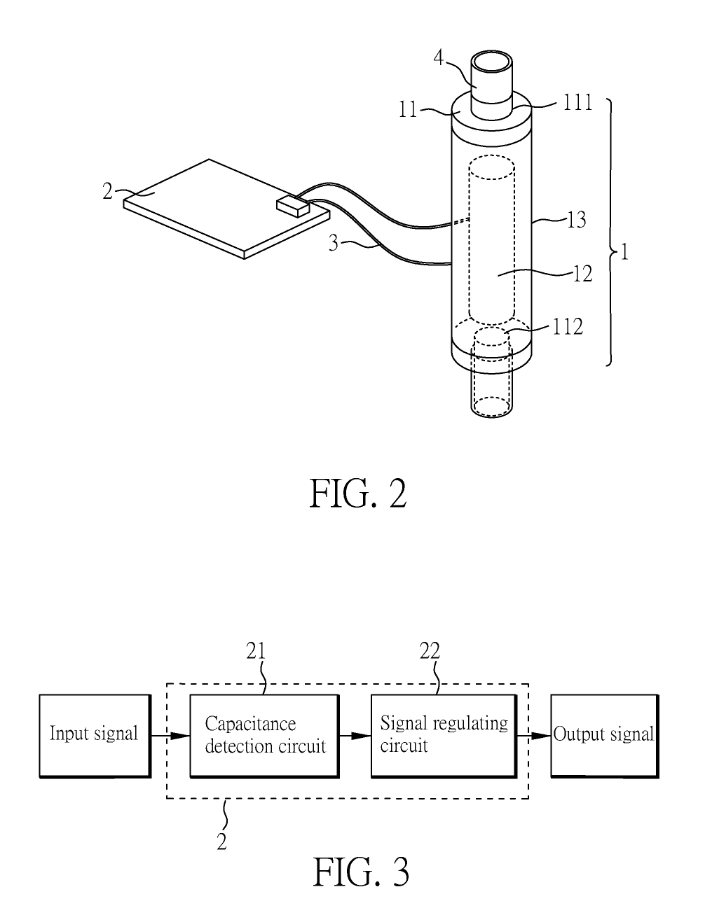

FIG. 2 shows a schematic diagram of another detection device of the present invention. The detection device of the present embodiment is substantially the same as Embodiment 1, except that the first conductor 12 is a cylindrical conductor, the second conductor 13 is a cylindrical conductor shell, the cylindrical conductor and the cylindrical conductor shell have the same center axis, and the first conductor 12 is disposed inside the second conductor 13 according to the present embodiment.

The materials and other settings used in the detection device of the present embodiment are the same as Embodiment 1, and thus the details are not described herein.

### Embodiment 3

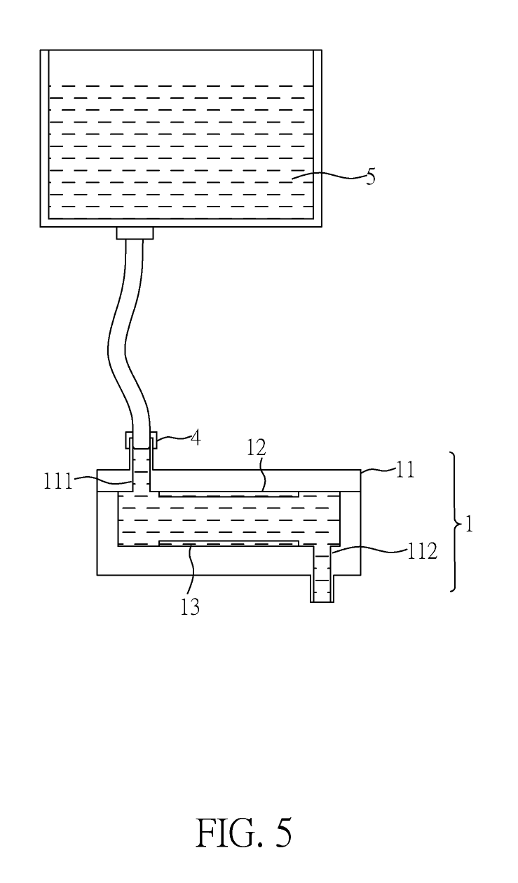

FIG. 5 shows a schematic diagram of a method for detection of an EDM liquid of the present invention. The present embodiment is exemplified by the detection device of Embodiment 1. However, the present invention is not limited thereto. The present invention may be combined with another detection device to form another embodiment.

The method for detection of electrical discharge machining liquid according to present invention comprises steps of: (A) filling a tank 1 with an electrical discharge machining liquid 5, wherein the tank 1 comprises a tank wall 11, a first conductor 12, and a second conductor 13; (B) measuring a voltage between the first conductor 12 and the second conductor 13 by an electronic device 2, wherein the electronic device 2 electrically connects to the first conductor 12 and the second conductor 13, and the electronic device 2 comprises a capacitance detection circuit 21; and (C) calculating a particle concentration or an equivalent dielectric constant of the electrical discharge machining liquid 5 on the basis of the measured voltage.

One embodiment of the present invention is to measure a particle concentration of EDM liquid under a condition of knowing the particle type of the EDM liquid.

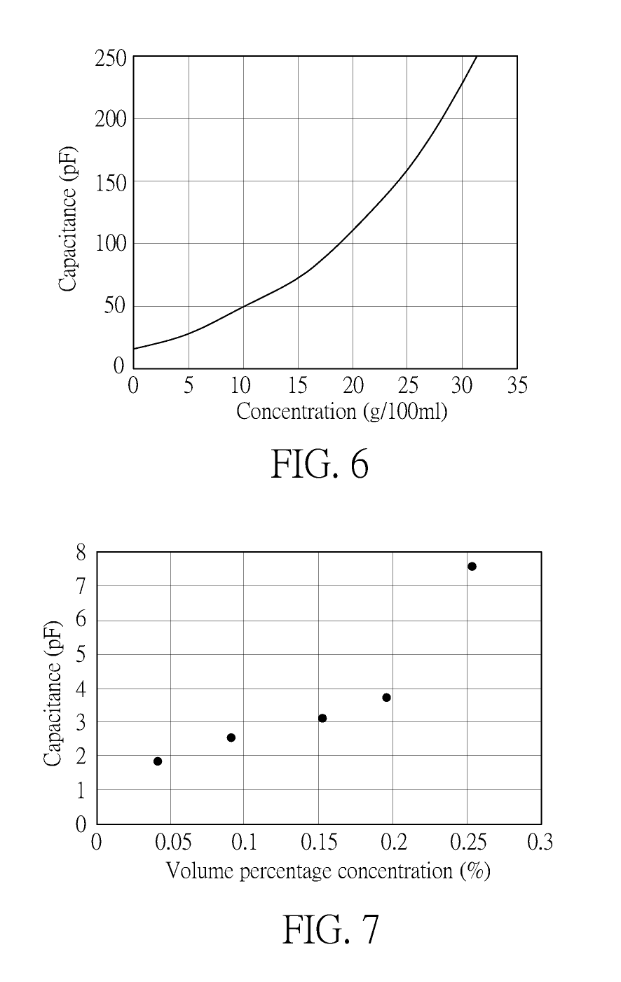

In the step (C), the capacitance may be calculated based on the measured voltage using formula: capacitance=charge/voltage (C=Q/V), but the present invention is not limited thereto. Any known calculation method for capacitance calculation in the art may be used to obtain the capacitance. The particle concentration of EDM liquid may be calculated on the basis of comparing the capacitance with a database of capacitance versus particle concentration. The EDM liquid may comprise a non-metal particle, a metal particle, or a combination thereof; the non-metal particle may comprise alumina, silicon, carbon, or a combination thereof; and the metal particle may comprise iron, gold, or a combination thereof. FIG. 6 shows a correlation between a capacitance of the EDM liquid having carbon particles and a particle concentration; FIG. 7 shows a correlation between a capacitance of the EDM liquid having iron particles and a particle concentration. Moreover, the EDM liquid used in the FIG. 6 and FIG. 7 is kerosene. Therefore, after the capacitance of the EDM liquid is obtained, the particle concentration and contamination level of the EDM liquid may be obtained by comparing the capacitance with a database of capacitance versus particle concentration so as to determine the timing of renewing the EDM liquid.

Yet another embodiment according to the present invention is to identify particle type of the EDM liquid by calculating without knowing the particle type in the EDM liquid. The step (C) may calculate a capacitance on the basis of the voltage, calculate an equivalent dielectric constant on the basis of the capacitance, calculate a dielectric constant of the particle in the EDM liquid on the basis of the equivalent dielectric constant, and identify a particle type in the EDM liquid on the basis of comparing the dielectric constant to a database of dielectric constant versus particle type.

The above specific embodiments shall be construed as merely illustrative, and not limitative of the remainder of the present invention in any way.

What is claimed is:

1. A method for detection of electrical discharge machining liquid, comprising steps of:
(A) filling a tank with an electrical discharge machining liquid, wherein the tank comprises a tank wall, a first conductor, and a second conductor;
(B) measuring a voltage between the first conductor and the second conductor by an electronic device, wherein the electronic device electrically connects to the first conductor and the second conductor, and the electronic device comprises a capacitance detection circuit; and
(C) calculating a particle concentration or an equivalent dielectric constant of the electrical discharge machining liquid on the basis of the measured voltage.

2. The method according to claim 1, wherein the step (C) calculates a capacitance on the basis of the measured voltage, and calculates the particle concentration or the equivalent dielectric constant of the electrical discharge machining liquid on the basis of the capacitance.

3. The method according to claim 2, wherein the step (C) calculates the particle concentration of the electrical discharge machining liquid on the basis of comparing the capacitance with a database of capacitance versus particle concentration.

4. The method according to claim 2, wherein the step (C) identifies a particle type of the electrical discharge machining liquid on the basis of comparing the equivalent dielectric constant to a database of dielectric constant versus particle type.

5. The method according to claim 1, wherein the electrical discharge machining liquid comprises a non-metal particle, a metal particle, or a combination thereof.

6. The method according to claim 5, wherein the non-metal particle is alumina, silicon, carbon, or a combination thereof; and the metal particle is iron, gold, or a combination thereof.

7. A detection device, comprising:
a tank, comprising:
a tank wall, having a first through hole and a second through hole;
a first conductor disposed in the tank; and
a second conductor disposed in the tank and disposed opposite to the first conductor;
wherein the first through hole and the second through hole are connected by the tank; and
an electronic device, comprising a capacitance detection circuit;
wherein the electronic device is electrically connected to the first conductor and the second conductor.

8. The detection device according to claim 7, wherein the first conductor and the second conductor are thin plate conductors, and the first conductor and the second conductor are disposed in parallel.

9. The detection device according to claim 7, wherein the first conductor is a cylindrical conductor, the second conductor is a cylindrical conductor shell, the cylindrical conductor and the cylindrical conductor shell have the same central axis, and the first conductor is disposed inside the second conductor.

10. The detection device according to claim 7, further comprising an electromagnetic driving device disposed at the first through hole.

11. The detection device according to claim 7, wherein the capacitance detection circuit is an AC bridge circuit.

12. The detection device according to claim 7, wherein the electronic device further comprises a microprocessor chip.
